(19) United States
(12) Patent Application Publication
(10) Pub. No.: US 2014/0252566 A1
(43) Pub. Date: Sep. 11, 2014

(54) SILICON-ON-DUAL PLASTIC (SODP) TECHNOLOGY AND METHODS OF MANUFACTURING THE SAME

(71) Applicant: RF Micro Devices, Inc., Greensboro, NC (US)

(72) Inventors: Daniel Charles Kerr, Oak Ridge, NC (US); Julio Costa, Oak Ridge, NC (US); Michael Carroll, Jamestown, NC (US); Don Willis, Kernersville, NC (US); Elizabeth Glass, Oak Ridge, NC (US)

(73) Assignee: RF Micro Devices, Inc., Greensboro, NC (US)

(21) Appl. No.: 14/260,909

(22) Filed: Apr. 24, 2014

Related U.S. Application Data
(63) Continuation-in-part of application No. 13/852,648, filed on Mar. 28, 2013.
(60) Provisional application No. 61/815,327, filed on Apr. 24, 2013.
(60) Provisional application No. 61/816,207, filed on Apr. 26, 2013.
(60) Provisional application No. 61/773,490, filed on Mar. 6, 2013.

(51) Int. Cl. H01L 29/02; H01L 21/02

(52) U.S. Cl. CPC H01L 29/02; H01L 21/0237
USPC 257/635; 438/479

(57) ABSTRACT

A semiconductor device and methods for manufacturing the same are disclosed. The semiconductor device includes a semiconductor stack structure having a first surface and a second surface. A first polymer having a high thermal conductivity and a high electrical resistivity is disposed on the first surface of the semiconductor stack structure. An exemplary method includes providing the semiconductor stack structure with the second surface in direct contact with a wafer handle. A next step involves removing the wafer handle to expose the second surface of the semiconductor stack structure. A following step includes disposing a second polymer having high thermal conductivity and high electrical resistivity directly onto the second surface of the semiconductor stack structure. Additional methods apply silicon nitride layers on the first surface and second surface of the semiconductor stack structure before disposing the first polymer and second polymer to realize the semiconductor device.

### RELATED APPLICATIONS

The present application claims priority to U.S. Provisional Patent Application No. 61/816,207, filed Apr. 26, 2013.

The present application claims priority to and is a continuation-in-part of U.S. patent application Ser. No. 13/852,648, filed Mar. 28, 2013, entitled “SEMICONDUCTOR DEVICE WITH A POLYMER SUBSTRATE AND METHODS OF MANUFACTURING THE SAME,” which claims priority to U.S. Provisional Patent Application No. 61/773,490, filed Mar. 6, 2013.

The present application is related to concurrently filed U.S. patent application Ser. No. ______, entitled “PATTERNED SILICON-ON-PLASTIC (SOP) TECHNOLOGY AND METHODS OF MANUFACTURING THE SAME,” which claims priority to U.S. Provisional Patent Application No. 61/815,327, filed Apr. 24, 2013.

All of the applications listed above are hereby incorporated herein by reference in their entireties.

### FIELD OF THE DISCLOSURE

This disclosure relates to semiconductor devices and methods for manufacturing the same.

### BACKGROUND

Radio frequency complementary metal oxide (RFCMOS) silicon-on-insulator (SOI) RF power switches are devices that are essential for practically every mobile handset currently on the market. Existing RFCMOS SOI technologies used to manufacture these devices provide excellent performance in increasingly complex multi-throw RF switches, tunable RF capacitance arrays, and antenna RF tuners. Conventional RFCMOS SOI technologies are built on high resistivity CMOS wafer handles that have resistivities ranging from 1000 Ohm-cm to 5000 Ohm-cm. A power switch employing RFCMOS SOI technology uses a high resistivity wafer handle so that a plurality of relatively low voltage field effect transistors (FETs) can be stacked while maintaining a desired isolation between the low voltage FETs.

In an RF switch application for third generation (3G) and fourth generation (4G) wireless applications, a high degree of RF device linearity and a relatively very low level of RF intermodulation under RF power conditions are crucial. Therefore, inherent nonlinearities in RF devices such as CMOS n-type field effect transistor (NFET) devices must be mitigated. Another source of nonlinearities is attributed to a high resistivity silicon handle wafer region interfaced with a buried oxide (BOX) dielectric region. One proposed solution for mitigating these nonlinearities includes a trap rich silicon/oxide interface that degrades carrier lifetimes in the silicon/oxide interface. Other proposed solutions for mitigating the nonlinearities due to the high resistivity handle region interfaced with the BOX dielectric region include harmonic suppression process techniques that include a series of process steps and heating treatments to minimize nonlinearities attributed to the high resistivity handle region interfaced with the BOX dielectric region. However, all the aforementioned proposed solutions add significant complexity and cost to CMOS SOI technology. What is needed are CMOS SOI based semiconductor devices and methods for manufacturing CMOS SOI devices that do not produce the nonlinearities attributed to the high resistivity silicon handle region interfaced with the BOX dielectric region.

### SUMMARY

A semiconductor device and methods for manufacturing the same are disclosed. The semiconductor device includes a semiconductor stack structure having a first surface including electrical contacts and a second surface that is on an opposite side of the semiconductor stack structure. A first polymer having a high thermal conductivity and a high electrical resistivity is disposed on the first surface of the semiconductor stack structure leaving the electrical contacts exposed, while a second polymer having a high thermal conductivity and a high electrical resistivity is disposed on the second surface of the semiconductor stack structure. In an additional embodiment, a first silicon nitride layer covers the first surface of the semiconductor stack structure, while a second silicon nitride layer covers the second surface of the semiconductor stack structure. In this additional embodiment, the first polymer is disposed on the first silicon nitride layer and the second polymer is disposed on the second silicon nitride layer, as opposed to being directly disposed on either the first surface or the second surface of the semiconductor stack structure.

An exemplary method includes providing the semiconductor stack structure with a first surface with electrical contacts and a second surface in direct contact with a wafer handle. A first polymer is disposed on the first surface of the semiconductor stack structure. A next step involves removing the wafer handle to expose the second surface of the semiconductor stack structure. A following step includes disposing a second polymer having high thermal conductivity and high electrical resistivity directly onto the second surface of the semiconductor stack structure. In another exemplary method, a first silicon nitride layer is deposited on the first surface of the semiconductor stack before the first polymer is disposed on the first silicon nitride layer. Another step deposits a second silicon nitride layer on the second surface of the semiconductor stack before the second polymer is disposed on the second silicon nitride layer.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description serve to explain the principles of the disclosure.

FIG. 1 is a cross-sectional diagram of a semiconductor stack structure interfaced with a relatively low resistivity silicon wafer handle.

FIG. 2 is a cross-sectional diagram of the semiconductor stack structure with a first polymer disposed on a first surface of the semiconductor stack structure.

FIG. 3 is a cross-sectional diagram of the semiconductor stack structure after the relatively low resistivity silicon wafer handle has been removed.

FIG. 4 is a cross-sectional diagram of the semiconductor stack structure after a second polymer has been disposed on the buried oxide (BOX) layer to realize the semiconductor device of the present disclosure.

FIG. 5 is a cross-sectional diagram of the semiconductor stack structure after a portion of the first polymer has been removed to expose the electrical contacts to realize a completed semiconductor device.

FIG. 6 is a cross-sectional diagram of the semiconductor device showing heat flow paths through the semiconductor device with the polymer after the semiconductor device has reached a steady state powered condition.

FIG. 7 is a process diagram that yields the semiconductor device of FIG. 6.

FIG. 8 is a specification table that lists thermal, mechanical, electrical, and physical specifications for an exemplary polymer material that is usable to form the polymer of the semiconductor device of the present disclosure.

FIG. 9 is a cross-sectional diagram of the semiconductor stack structure after a first silicon nitride layer has been deposited on a first surface of the semiconductor stack structure.

FIG. 10 is a cross-sectional diagram of the semiconductor stack structure after the first polymer has been deposited on the first silicon nitride layer.

FIG. 11 is a cross-sectional diagram of the semiconductor stack structure after the silicon wafer handle has been removed.

FIG. 12 is a cross-sectional diagram of the semiconductor stack structure after a second silicon nitride layer has been deposited on a second surface of the semiconductor stack structure.

FIG. 13 is a cross-sectional diagram of the semiconductor stack structure after a second polymer has been deposited on the second silicon nitride layer.

FIG. 14 is a cross-sectional diagram of the semiconductor stack structure after a portion of the first polymer has been removed to expose the electrical contacts.

FIG. 15 is a process diagram that yields a semiconductor device of FIG. 14.

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

It will be understood that when an element such as a layer, region, or substrate is referred to as being “over,” “on,” “disposed on,” “in,” or extending “onto” another element, it can be directly over, directly on, directly in, or extend directly onto the other element or intervening elements may also be present. In contrast, when an element is referred to as being “directly over,” “directly on,” “directly disposed on”, “directly in,” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures. Moreover, the phrase “electrically resistive” used herein means having a resistance greater than 10⁶ Ohm-cm. Also, the phrase “thermally conductive” used herein means having a thermal conductivity greater than 2 watts per meter Kelvin (W/mK).

Traditional RFCMOS SOI technologies have reached a fundamental barrier due to limitations inherent to silicon wafer handles that prevent the relatively better insulating characteristics available in group IV, group III-V, or sapphire wafer handles. The disclosed semiconductor device replaces the silicon wafer handle with a polymer. As such, the semiconductor device of this disclosure eliminates the need for a high resistivity silicon wafer handle in a provided semiconductor stack structure.

Advanced silicon wafer handles for RF switch applications have resistivities that range from 1000 Ohm-cm to 5000 Ohm-cm and are significantly more costly than standard silicon wafer handles having much lower resistivities. Moreover, relatively complex process controls are needed to realize high resistivity in advanced silicon wafer handles. For these reasons standard silicon wafer handles are used ubiquitously in standard SOI technologies. However, standard silicon wafer handles with their much lower resistivities are not conducive for stacking a plurality of relatively low voltage field effect transistors (FETs) while maintaining a desired isolation between the low voltage FETs. Fortunately, the polymer of the present disclosure replaces the silicon wafer handle and thus, eliminates the problems associated with both high and low resistivity silicon wafer handles.

Additionally, the methods of the present disclosure allow for an immediate migration to 300 mm wafer handles for use in RF power switch applications. This is an important development since there is currently no commercially viable high volume supply of high resistivity RFSOI wafer handles in the 300 mm wafer diameter format. Fabricating the present semiconductor devices on 300 mm diameter wafers would provide a significant improvement in die costs. Moreover, the need for a trap rich layer and/or harmonic suppression techniques is eliminated, thereby resulting in a significantly simpler process flow and lower cost.

Further still, the polymer is expected to eliminate RF nonlinear effects resulting from the interface between the BOX layer and the silicon wafer handle used in traditional semiconductor processes to manufacture RF switch devices. The present methods realize RF switch devices that have linear characteristics relatively close to ideal linear characteristics.

Additionally, the semiconductor device of this disclosure offers a near ideal voltage stacking of NFET transistors. Traditionally, the number of NFET devices that can be stacked is limited by silicon wafer handle resistivity combined with the interface effects between the BOX layer and the silicon wafer handle. This issue essentially limits the number of practical NFET transistors that can be stacked and thus, limits the highest RF operating voltage for the resulting NFET transistor stack. Replacing silicon wafer handles with the polymer of the present disclosure allows relatively many more NFET transistors to be practically ideally stacked. The resulting semiconductor device is operable at relatively much higher RF power levels and RMS voltages than is traditionally allowable on silicon handle wafer technologies.

Furthermore, the highest RF frequency of operation of RF power switches built with the disclosed polymer can be extended beyond the highest frequency of operation achievable with traditional RFCMOS SOI technologies. Typically, a silicon wafer handle resistivity is in the range of 1000-3000 Ohm-cm, which effectively imposes an operational high frequency limit. The resulting resistivity of the polymer region in the semiconductor device taught in this disclosure is several orders of magnitude higher than what is achieved in high resistivity silicon. For instance, there are polymers with nearly ideal electrically insulating characteristics, with resistivity values similar to what is obtained in gallium arsenide (GaAs) and sapphire semi-insulating wafer handles.

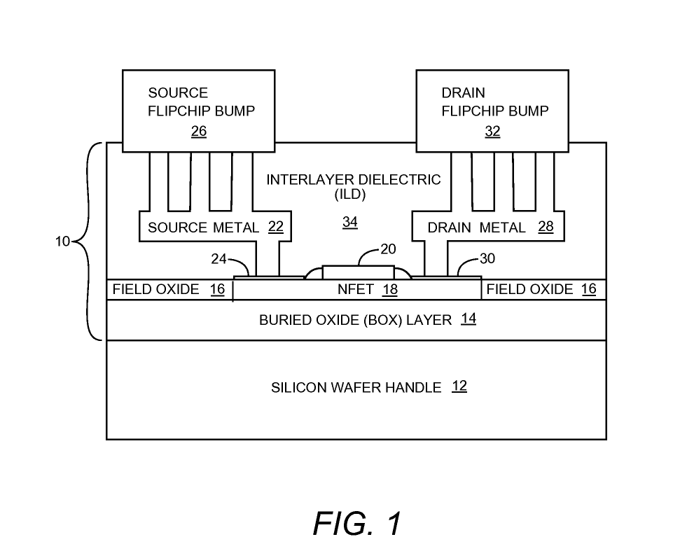

FIG. 1 is a cross-sectional diagram of a semiconductor stack structure 10 interfaced with a relatively low resistivity silicon wafer handle 12. In the exemplary case of FIG. 1, the semiconductor stack structure 10 includes a buried oxide (BOX) layer 14, a field oxide layer 16, and an NFET device layer 18, with a gate 20. A source metal conductor 22 couples a source contact 24 with a source flipchip bump 26. Similarly, a drain metal conductor 28 couples a drain contact 30 with a drain flipchip bump 32. An interlayer dielectric (ILD) 34 protects the gate 20 and supports the source flipchip bump 26 and the drain flipchip bump 32.

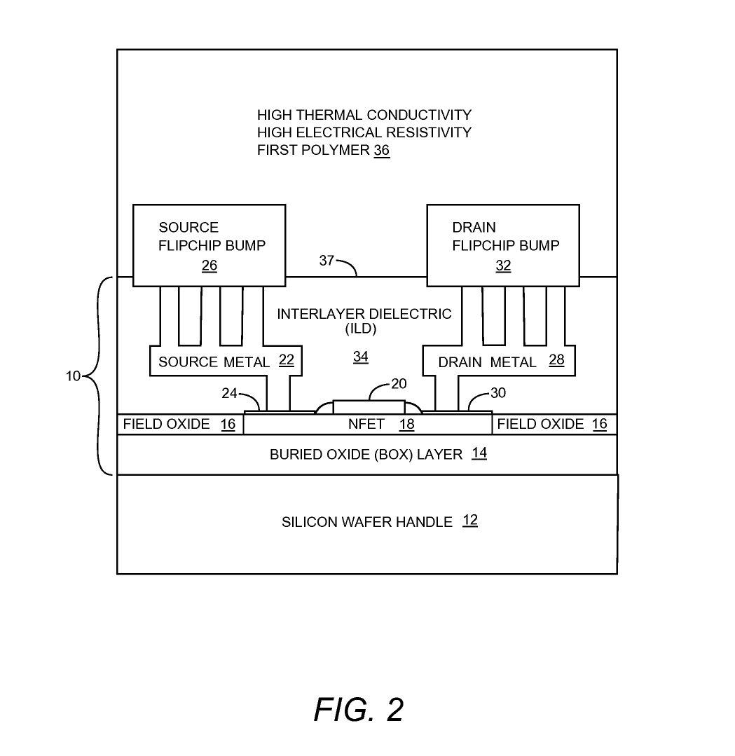

FIG. 2 is a cross-sectional diagram of the semiconductor stack structure 10 after a first polymer 36 having a relatively high thermal conductivity and relatively high electrical resistivity is disposed on a first surface 37 of the semiconductor stack 10 that includes the source flipchip bump 26 and the drain flipchip bump 32. The first polymer 36 has a thickness that at least encapsulates the source flipchip bump 26 and the drain flipchip bump 32 to protect them from damage during subsequent processing steps.

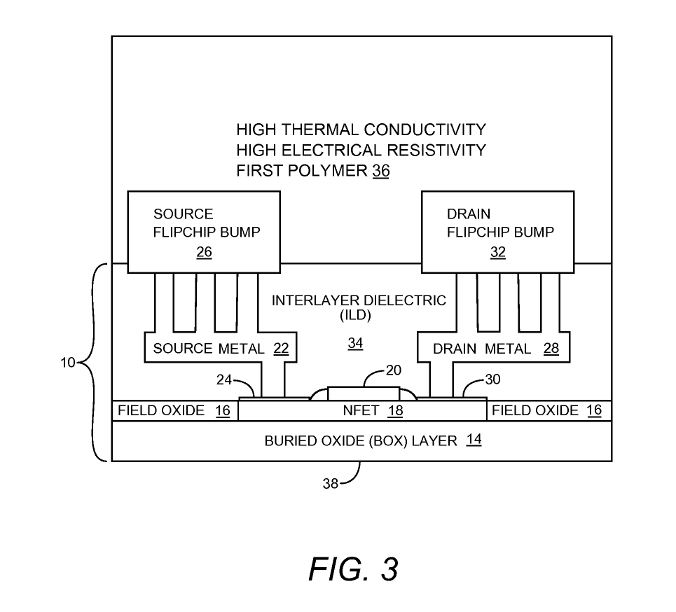

FIG. 3 is a cross-sectional diagram of the semiconductor stack structure 10 after the relatively low resistivity silicon wafer handle 12 has been removed. Once the semiconductor stack structure 10 is protected by the first polymer 36, the silicon wafer handle 12 may be removed by a number of different techniques. One technique uses a conventional grind operation that removes a majority of the silicon wafer handle 12 followed by a selective wet or dry etch step of the remaining silicon wafer handle 12, and selectively stopping at a second surface 38 of the semiconductor stack structure 10. In this exemplary case, the second surface 38 is also the exposed surface of the BOX layer 14. However, it is to be understood that the exposed portion of the semiconductor stack structure 10 can be slightly deeper than the original second surface 38 depending on etch duration, etc. Other techniques for removal of the silicon wafer handle 12 exist and are well documented in the literature. Some of these other techniques are based on dry or wet etch processes. The process used to remove the silicon wafer handle 12 is not particularly relevant to the present disclosure. However, it is desirable for the removal of the silicon wafer handle 12 to be accomplished without damaging the BOX layer 14 and the remainder of the semiconductor stack structure 10 as well as the source flipchip bump 26 and the drain flipchip bump 32.

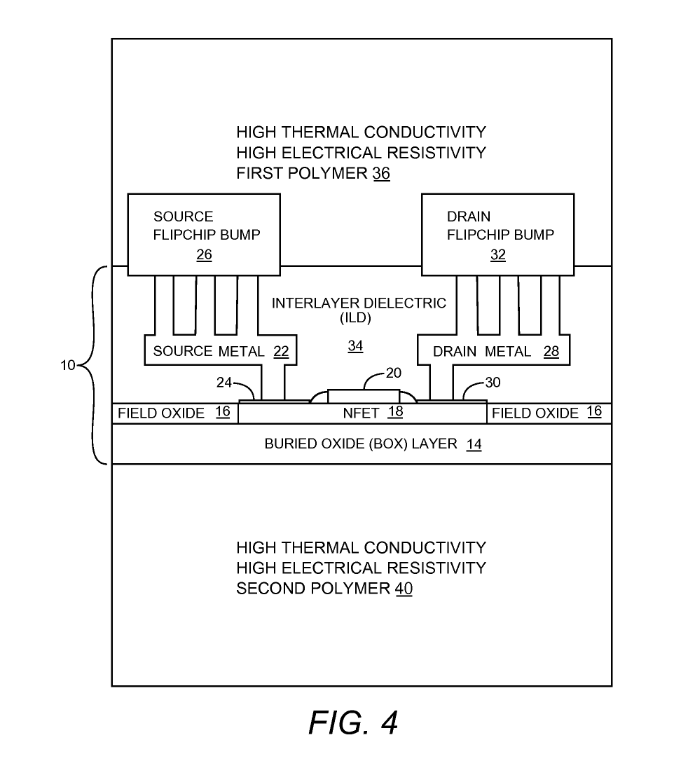

FIG. 4 is a cross-sectional diagram of the semiconductor stack structure 10 after a second polymer 40 has been disposed on the BOX layer 14. The polymer material making up the first polymer 36 and the second polymer 40 has a unique set of characteristics in that the polymer material is both a relatively excellent electrical insulator and a relatively excellent heat conductor. Typical polymer materials making up common plastic parts are extremely poor conductors of heat. Poor heat conduction is a common characteristic of plastics normally used in an over-mold operation. However, there are engineered polymer materials that do provide relatively excellent heat conduction. Various formulations for such polymers yield thermal conductivities that range from greater than 2 Watts per meter Kelvin (W/mK) to around about 50 W/mK. In one embodiment, the thermal conductivity of the polymer ranges from around about 50 W/mK to around about 500 W/mK. Future enhancements in polymer science may provide additional improvements in terms of thermal conductivity while maintaining nearly ideal electrical insulating characteristics in the polymer. The structure of this disclosure benefits from the maximization of the polymer thermal conductivity and it should be understood that an upper bound of polymer thermal conductivity nears a theoretical thermal conductivity of carbon nanotubes and graphene, which is 6600 W/mK.

It is desirable that a polymer material usable for the first polymer 36 and second polymer 40 be relatively strongly bondable to the second surface 38 of the semiconductor stack structure 10. For example, the polymer material needs a bonding strength that allows the semiconductor stack structure 10 to remain permanently bonded after additional processing steps, as well as throughout the operational lifetime of a semiconductor device comprising the semiconductor stack structure 10. Moreover, a desirable thickness for the first polymer 36 and the second polymer 40 ranges from around about 100 μm to around about 500 μm, but other desirable thicknesses for the first polymer 36 and the second polymer 40 can be thinner or thicker depending on the characteristics of the polymer material used to make up the first polymer 36 and the second polymer 40.

The polymer material making up the first polymer 36 and the second polymer 40 should also be a good electrical insulator. In general, the electrical resistivity of the first polymer 36 and the second polymer 40 should be greater than 10⁶ Ohm-cm. In at least one embodiment, the polymer has a relatively high electrical resistivity that ranges from around about 10¹² Ohm-cm to around about 10¹⁶ Ohm-cm. In combination with relatively high electrical resistivity, the thermal conductivity of the first polymer 36 and the second polymer 40 is on the order of the thermal conductivity of typical semiconductors, which is typically greater than 2 W/mK. In one embodiment, the thermal conductivity of the first polymer 36 and the second polymer 40 ranges from greater than 2 W/mK to around about 10 W/mK. In yet another embodiment, the thermal conductivity of the first polymer 36 and the second polymer 40 ranges from around about 10 W/mK to around about 50 W/mK. As polymer science provides materials with additional thermal conductivities, these materials can be utilized in the semiconductor device of this disclosure. The semiconductor device of this disclosure benefits from the maximization of the polymer thermal conductivity and it should be understood that an upper bound of polymer thermal conductivity nears a theoretical thermal conductivity of carbon nanotubes and graphene, which is 6600 W/mK.

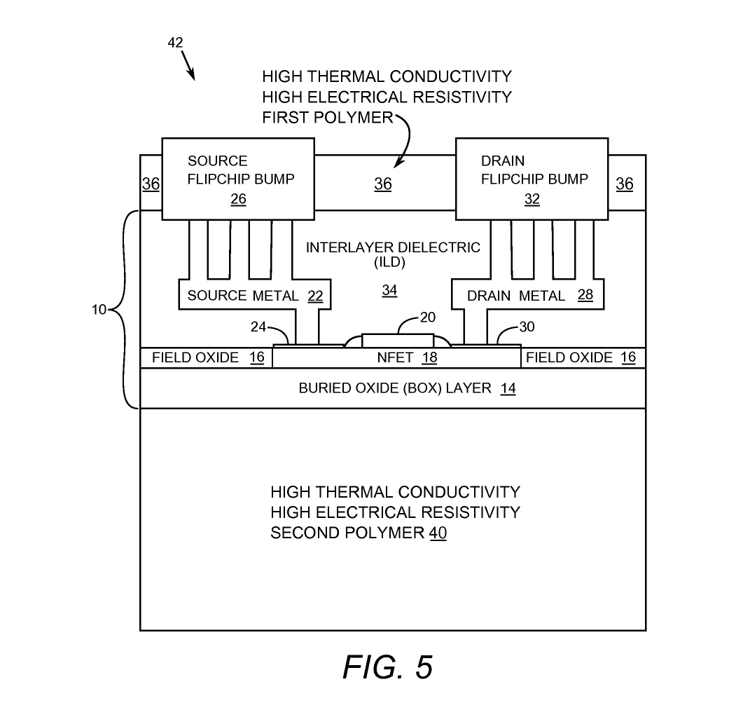

FIG. 5 is a cross-sectional diagram of the semiconductor stack structure 10 after a portion of the first polymer 36 has been removed to expose the source flipchip bump 26 and the drain flipchip bump 32 to realize a completed semiconductor device 42. An exemplary process for removing a portion of the first polymer 36 includes a sample grind operation to etch back the first polymer 36 to expose at least electrically conductive contact patches of the source flipchip bump 26 and the drain flipchip bump 32. In one embodiment, the source flipchip bump 26 and the drain flip chip bump 32 should protrude from the remaining portion of the first polymer 36.

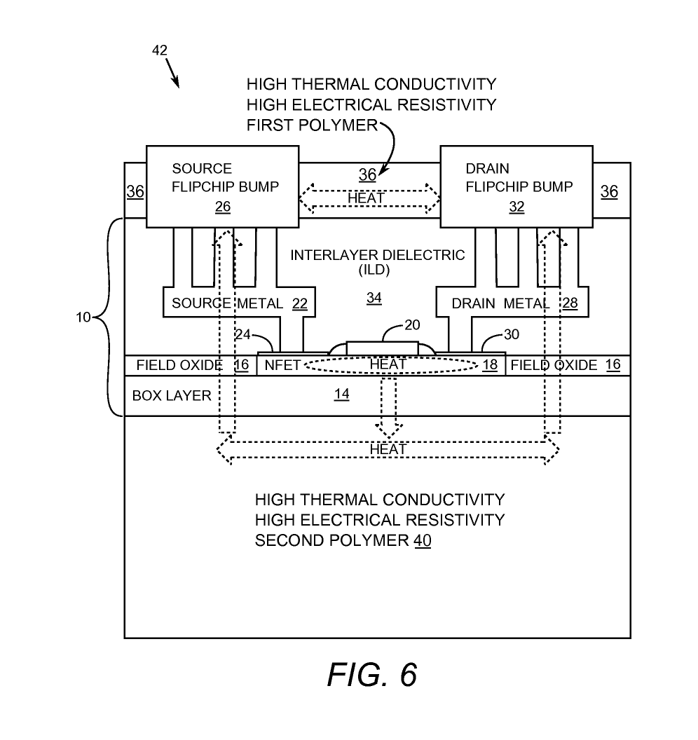

FIG. 6 is a cross-sectional diagram of the semiconductor device showing heat flow paths through the semiconductor device 42 with the second polymer 40 after the semiconductor device 42 has reached a steady state powered condition. Under normal operation, heat is generated by energy losses in the NFET 18. An origin for the heat generated is represented by a dashed oval in the NFET 18 adjacent to the BOX layer 14. The flow of heat is represented by dashed arrows. As usual for high performance RF applications, the semiconductor device 42 is flipchip mounted in its final application. As such, the heat to be extracted is transferred by thermal conduction to the source flipchip bump 26 and the drain flipchip bump 32. Thermal analysis of typical SOI technologies indicates that unless the silicon wafer handle 12 (FIG. 1) is replaced with a good thermal conductive material, the NFET 18 quickly overheats under nominal conditions and essentially becomes very unreliable and likely fails. Under normal conditions and design rules, back-end-of-line metallization layers (not shown) provide too high a thermal resistance path to be used effectively as a means to dissipate the heat generated by the device. The second polymer 40 accomplishes effectively the same function as the original silicon wafer handle 12 from a thermal management point of view while also providing much improved linear characteristics and effectively much higher electrical resistivity than the 1 kOhm-cm electrical resistivity of the silicon wafer handle 12.

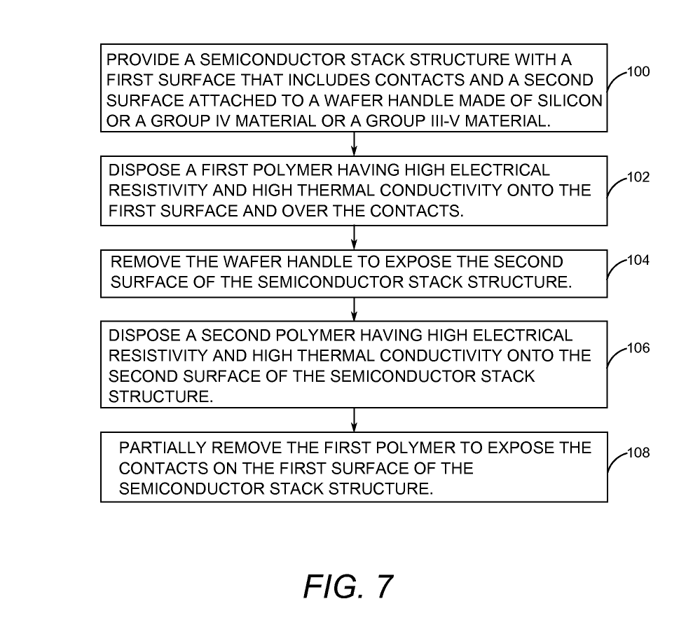

FIG. 7 is a process diagram that yields the semiconductor device 42 having the second polymer 40 disposed on the second surface 38, which in this exemplary case is an exposed portion of the semiconductor stack structure 10. However, it is to be understood that the exposed portion of semiconductor stack structure 10 can be slightly deeper than the original second surface 38 depending on etch duration, etc. The exemplary process begins with providing the semiconductor stack structure 10 having the second surface 38 of the BOX layer 14 in direct contact with the silicon wafer handle 12 (step 100). While the semiconductor stack structure 10 is attached to the silicon wafer handle 12 at the beginning of the process, it is to be understood that a wafer handle made of other group IV or III-V semiconductors is also usable in place of the silicon wafer handle 12. The first polymer 36 having a high electrical resistivity and a high thermal conductivity is disposed to completely cover the contacts made up of the source flipchip bump 26 and the drain flipchip bump 32 (step 102). The process then continues by removing the silicon wafer handle 12 to expose the second surface 38 of the semiconductor stack structure 10 (step 104). The second polymer 40 can then be disposed on the second surface 38 using various polymer material disposing methods (step 106). Such methods for attaching the polymer 42 to the second silicon nitride layer 46 of the semiconductor stack structure 10 include, but are not limited to, injection molding, spin deposition, spray deposition, and pattern dispensing of polymer material directly onto the second surface 38 of the semiconductor stack structure 10. Once the second polymer 40 is attached to the second surface 38 of the semiconductor stack structure 10, the first polymer 36 is partially removed to expose the contacts made up of the source flipchip bump 26 and the drain flipchip bump 32 (step 108).

The semiconductor device 42 can then be cleaned with common chemical solvents and/or plasma cleaning processes. The semiconductor device 42 can then be singulated from an original wafer (not shown) into individual die by a number of different conventional processes. Typically, a saw operation that cuts through the semiconductor stack structure 10 and first polymer 36 and the second polymer 40 is one method of die singulation. Other singulation methods such as laser sawing, laser scribing or diamond scribing can be used as alternatives.

It should be noted that the semiconductor device and methods taught in this disclosure begin with a conventionally manufactured RFSOI CMOS wafer which in this exemplary case is the semiconductor stack structure 10 disposed on the silicon wafer handle 12. However, one distinction is that there is no need for the silicon wafer handle 12 to have high resistivity, since the silicon wafer handle 12 is removed and does not become part of the semiconductor device 42. If the semiconductor device 42 requires flipchip packaging, it should ideally already include the source flipchip bump 26 and the drain flipchip bump 32, although such a requirement may not be necessary depending on the specific characteristics of the bump or pillar packaging technology employed. In this exemplary case, it is assumed that a wafer process was completed through bumping.

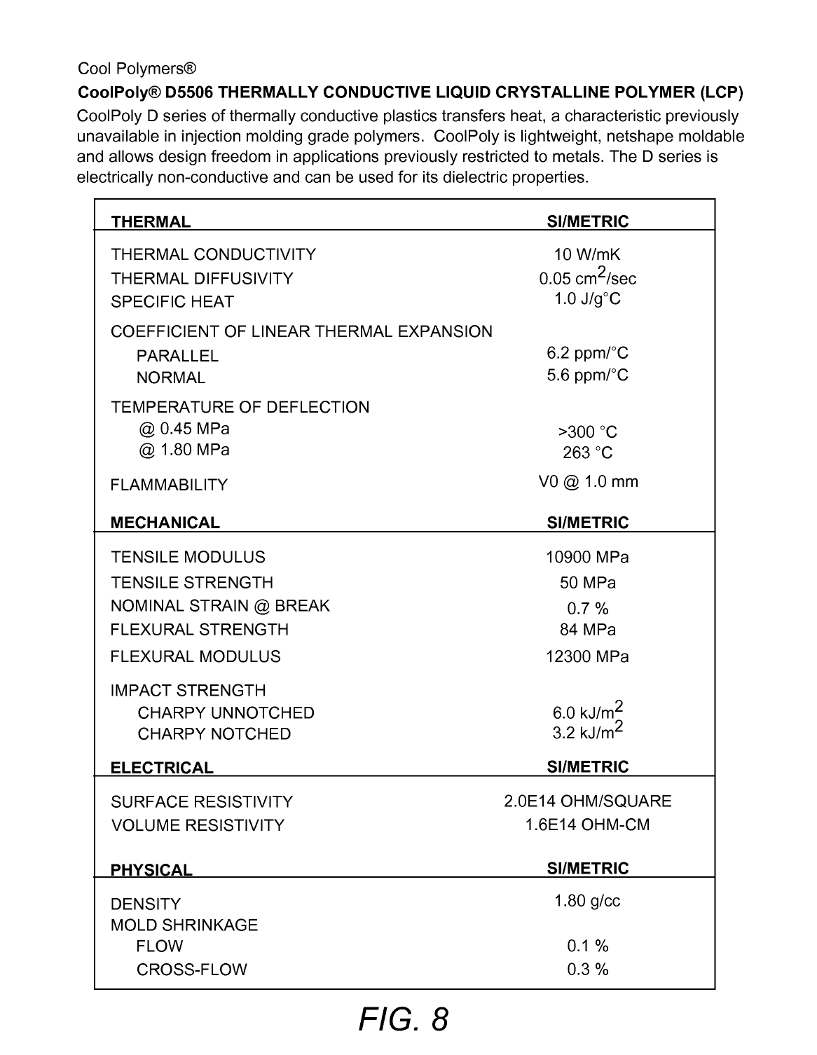

FIG. 8 is a specification table that lists thermal, mechanical, electrical, and physical specifications for an exemplary polymer material that is usable to form the first polymer 36 and the second polymer 40 of the semiconductor device 42. The exemplary polymer material specified in the specification table of FIG. 8 is made by Cool Polymers® and is sold under the label “CoolPoly® D5506 Thermally Conductive Liquid Crystalline Polymer (LCP).” It is to be understood that the specification table of FIG. 8 only provides exemplary specifications and that a variety of mechanical and physical properties are available within the scope of the present disclosure. Moreover, the quantitative values for the thermal and electrical properties provided in the table of FIG. 8 only represent exemplary values that are within the range of thermal and electrical properties already discussed in the above disclosure. The first polymer 36 and the second polymer 40 are a thermoplastic such as polyamides that include nylon. Other suitable thermoplastics include, but are not limited to, Acrylonitrile Butadiene Styrene (ABS), Polyetheretherketone (PEEK) and Polysulfone. In some embodiments, the first polymer and the second polymer can be a thermoset plastic, such as a two part epoxy resin. Moreover, the first polymer 36 and the second polymer 40 typically include an admixture for increasing thermal conductivity. Examples of suitable thermal conductivity enhancing admixtures include ceramic powders, which include, but are not limited to boron nitride powder and aluminum nitride powder.

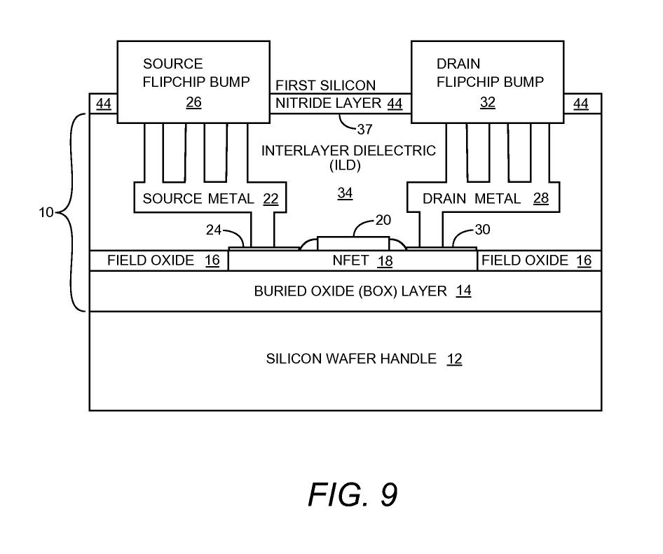

FIG. 9 is a cross-sectional diagram of the semiconductor stack structure 10 after a first silicon nitride layer 44 has been deposited on the first surface 37 of the semiconductor stack structure 10 that includes the source flipchip bump 26 and the drain flipchip bump 32. The first silicon nitride layer 44 is an adhesion promoter for bonding a first polymer 36 to the semiconductor stack structure 10.

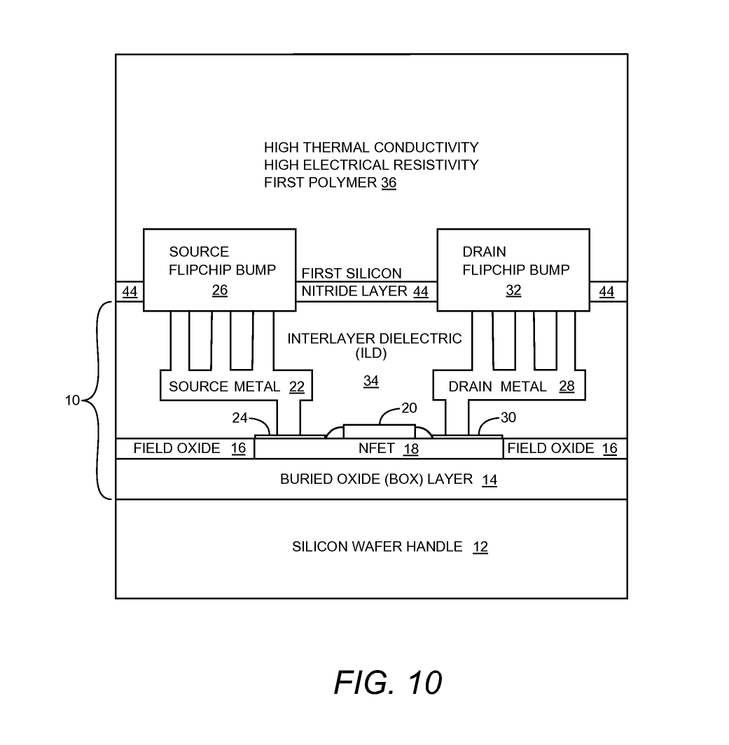

FIG. 10 is a cross-sectional diagram of the semiconductor stack structure 10 after a first polymer 36 has been deposited on the first silicon nitride layer 44. The first polymer 36 has a high electrical resistivity and a high thermal conductivity and completely covers the electrical contacts made up of the source flipchip bump 26 and the drain flipchip bump 32. The electrical contacts are completely covered by the first polymer 36 to protect them subsequent processing steps.

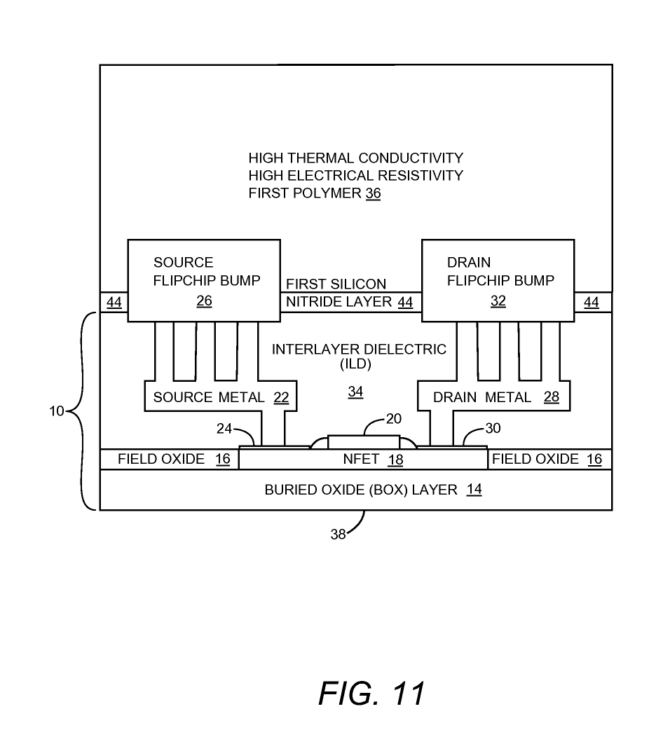

FIG. 11 is a cross-sectional diagram of the semiconductor stack structure 10 after the relatively low resistivity silicon wafer handle 12 has been removed. Once the semiconductor stack structure 10 is protected by the first polymer 36, the silicon wafer handle 12 may be removed by a number of different techniques. One technique uses a conventional grind operation that removes a majority of the silicon wafer handle 12 followed by a selective wet or dry etch step of the remaining silicon wafer handle 12, and selectively stopping at a second surface 38 of the semiconductor stack structure 10. In this exemplary case, the second surface 38 is also the exposed surface of the BOX layer 14. However, it is to be understood that the exposed portion of the semiconductor stack structure 10 can be slightly deeper than the original second surface 38 depending on etch duration, etc. Other techniques for removal of the silicon wafer handle 12 exist and are well documented in the literature. Some of these other techniques are based on dry or wet etch processes. The process used to remove the silicon wafer handle 12 is not particularly relevant to the present disclosure. However, it is desirable for the removal of the silicon wafer handle 12 to be accomplished without damaging the BOX layer 14 and the remainder of the semiconductor stack structure 10 as well as the source flipchip bump 26 and the drain flipchip bump 32.

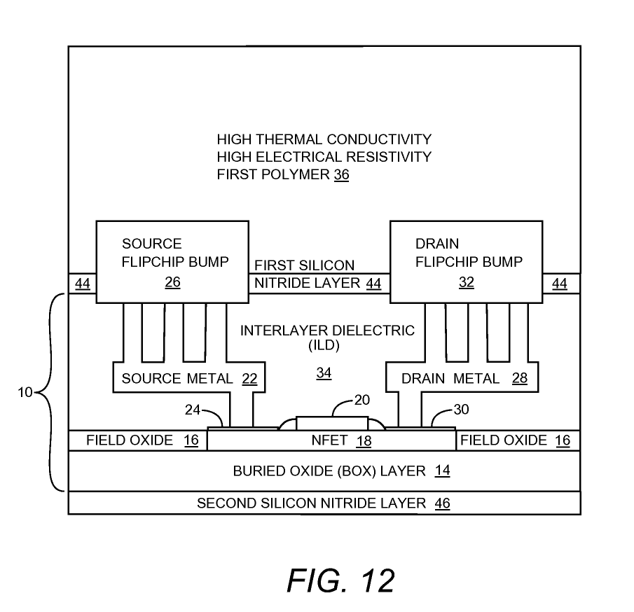

FIG. 12 is a cross-sectional diagram of the semiconductor stack structure 10 after a second silicon nitride layer 40 has been deposited on the second surface 38 of the semiconductor stack structure 10. The second polymer 40 can then be disposed on the second silicon nitride layer 46 using various polymer material disposing methods.

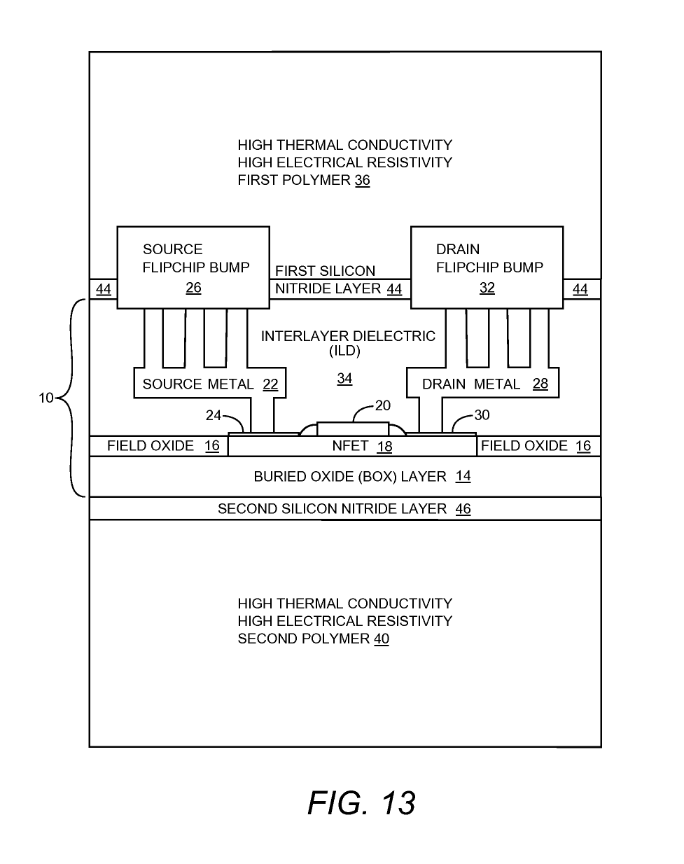

FIG. 13 is a cross-sectional diagram of the semiconductor stack structure 10 after the second polymer 40 has been disposed on the second silicon nitride layer 46. In one respect, the first silicon nitride layer 44 and the second silicon nitride layer 46 are adhesion promoters for bonding the first polymer 36 and the second polymer 40 to the semiconductor stack structure 10. In another respect, the first silicon nitride layer 44 and the second silicon nitride layer 46 prevent or at least resist a diffusion of moisture within the first polymer 36 and the second polymer 40 from reaching the BOX layer 14 or other critical device layers that may include complementary metal oxide semiconductor (CMOS) layers. The benefit of having a moisture barrier formed by the first silicon nitride layer 44 and the second silicon nitride layer 46 is the prevention of a degradation of function of devices that make up the semiconductor stack 10. The first silicon nitride layer 44 and the second silicon nitride layer 46 may be deposited as an example via a plasma enhanced chemical vapor deposition (PECVD) system by the decomposition of silane and nitrogen gases, as commonly known to those skilled in the art. Such PECVD systems operate at temperatures typically between room temperature and 350° C. The first silicon nitride layer 44 and the second silicon nitride layer 46 may also be deposited by other techniques including liquid phase chemical vapor deposition (LPCVD) and sputtered from a nitride target using RF sputtering. The first silicon nitride layer 44 does not significantly impact the thermal conductivity provided by the first polymer 36. Likewise, the second silicon nitride layer 46 does not significantly impact the thermal conductivity provided by the second polymer 40. In one embodiment, the thickness of either of the first silicon nitride layer 44 and the second silicon nitride layer 46 ranges from around about 100 Å to around about 1000 Å. In another embodiment, the thickness of either of the first silicon nitride layer 44 and the second silicon nitride layer 46 ranges from around about 1000 Å to around about 5000 Å. In yet another embodiment, the thickness of either of the first silicon nitride layer 44 and the second silicon nitride layer 46 ranges from around about 5000 Å to around about 10,000 Å.

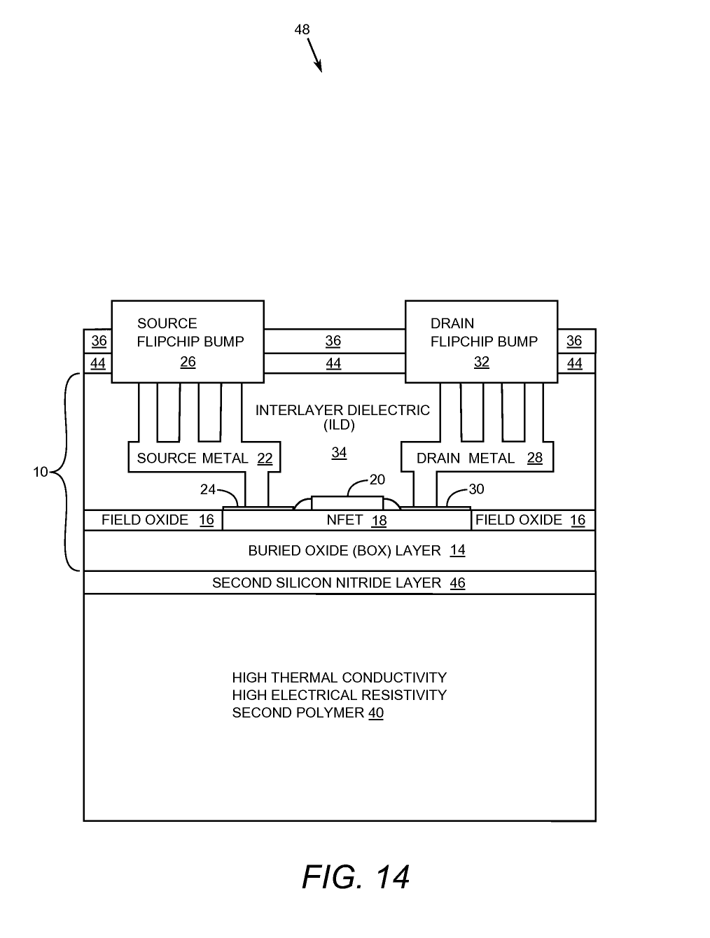

FIG. 14 is a cross-sectional diagram of the semiconductor stack structure 10 after a portion of the first polymer 36 has been removed to expose the source flipchip bump 26 and the drain flipchip bump 32 to realize a completed semiconductor device 48. An exemplary process for removing a portion of the first polymer 36 includes a sample grind operation to etch back the first polymer 36 to expose at least electrically conductive contact patches of the source flipchip bump 26 and the drain flipchip bump 32. In one embodiment, the source flipchip bump 26 and the drain flip chip bump 32 should protrude from the remaining portion of the first polymer 36.

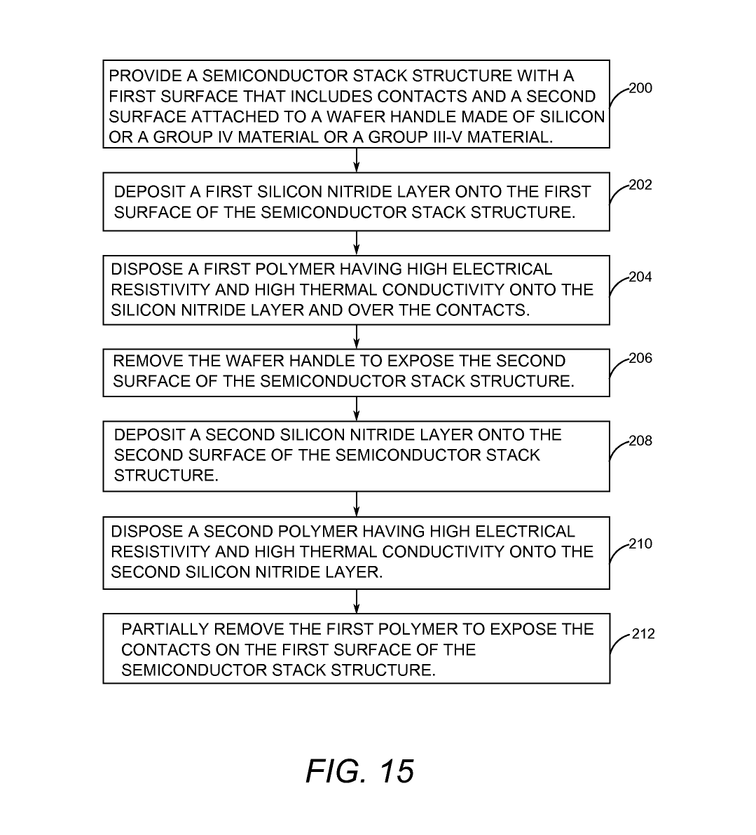

FIG. 15 is a process diagram that yields the semiconductor device having the first polymer 36 disposed on the first silicon nitride layer 44 and the second polymer 40 disposed on the second silicon nitride layer 46. An exemplary process begins with providing the semiconductor stack structure 10 having the first surface 37 including contacts such as source flipchip bump 26 and drain flipchip bump 32, along with the second surface 38 of the BOX layer 14, in direct contact with the silicon wafer handle 12 (step 200). While the semiconductor stack structure 10 is attached to the silicon wafer handle 12 at the beginning of the process, it is to be understood that a wafer handle made of other group IV or III-V semiconductors is also usable in place of the silicon wafer handle 12.

The first silicon nitride layer 44 is deposited on the first surface 37 of the semiconductor stack structure 10 that includes the contacts made up of the source flipchip bump 26 and the drain flipchip bump 32 (step 202). The first polymer 36 having a high electrical resistivity and a high thermal conductivity is disposed on the first silicon nitride layer 44 to completely cover the contacts made up of the source flipchip bump 26 and the drain flipchip bump 32 (step 204). The process then continues by removing the silicon wafer handle 12 to expose the second surface 38 of the semiconductor stack structure 10 (step 206). Next, a second silicon nitride layer 46 is deposited on the second surface 38 of the semiconductor stack structure 10 (step 208). The second polymer 40 can then be disposed on the second silicon nitride layer 46 using various polymer material disposing methods (step 210). Such methods for attaching the polymer 42 to the second silicon nitride layer 46 of the semiconductor stack structure 10 include, but are not limited to, injection molding, spin deposition, spray deposition, and pattern dispensing of polymer material directly onto the second silicon nitride layer 46. Once the second polymer 40 is attached to the silicon nitride layer 46, the first polymer 36 is partially removed to expose the contacts made up of the source flipchip bump 26 and the drain flipchip bump 32 (step 212).

Those skilled in the art will recognize improvements and modifications to the embodiments of the present disclosure. All such improvements and modifications are considered within the scope of the concepts disclosed herein and the claims that follow.

What is claimed is:

1. A semiconductor device comprising:
a semiconductor stack structure having a first surface including electrical contacts and a second surface that is on an opposite side of the semiconductor stack structure;
a first polymer disposed on the first surface of the semiconductor stack structure leaving the electrical contacts exposed; and
a second polymer disposed on the second surface of the semiconductor stack structure.

2. The semiconductor device of claim 1 wherein the first polymer and the second polymer include a ceramic admixture.

3. The semiconductor device of claim 2 wherein the ceramic admixture is boron nitride powder.

4. The semiconductor device of claim 2 wherein the ceramic admixture is aluminum nitride powder.

5. The semiconductor device of claim 1 wherein the first polymer and the second polymer comprise a polysulfone compound.

6. The semiconductor device of claim 1 wherein the first polymer and second polymer are thermoplastic.

7. The semiconductor device of claim 6 wherein the thermoplastic is nylon.

8. The semiconductor device of claim 6 wherein the thermoplastic is liquid crystal polymer.

9. The semiconductor device of claim 1 wherein the first polymer and the second polymer are thermoset plastics.

10. The semiconductor device of claim 1 wherein the semiconductor stack structure has a buried oxide (BOX) layer that includes the second surface of the semiconductor stack structure.

11. The semiconductor device of claim 1 wherein a thermal conductivity of the first polymer and the second polymer each range from greater than 2 watts per meter Kelvin (W/mK) to around about 10 W/mK.

12. The semiconductor device of claim 1 wherein a thermal conductivity of the first polymer and the second polymer each range from around about 10 W/mK to around about 50 W/mK.

13. The semiconductor device of claim 1 wherein a thermal conductivity of the first polymer and second polymer each range from around about 50 W/mK to around about 6600 W/mK.

14. The semiconductor device of claim 1 wherein an electrical resistivity of the first polymer and second polymer each range from around about 10¹² Ohm-cm to around about 10¹⁶ Ohm-cm.

15. The semiconductor device of claim 1 wherein an electrical resistivity of the first polymer and the second polymer each range from around about 10⁶ Ohm-cm to around about 10¹² Ohm-cm.

16. The semiconductor device of claim 1 further comprising a first silicon nitride layer deposited on the first surface between the first polymer and semiconductor stack structure and a second silicon nitride layer deposited on the second surface between the second polymer and the semiconductor stack structure.

17. The semiconductor device of claim 16 wherein a thickness of the first silicon nitride layer and a thickness of the second silicon nitride layer each range from greater than 100 Å to around about 5000 Å.

18. The semiconductor device of claim 1 further comprising a silicon nitride layer deposited on the first surface between the first polymer and the semiconductor stack structure.

19. The semiconductor device of claim 18 wherein a thickness of the silicon nitride layer ranges from greater than 100 Å to around about 5000 Å.

20. The semiconductor device of claim 1 further comprising a silicon nitride layer deposited on the second surface between the second polymer and the semiconductor stack structure.

21. The semiconductor device of claim 20 wherein a thickness of the silicon nitride layer ranges from greater than 100 Å to around about 5000 Å.

22. A method of manufacture for a semiconductor device comprising:
providing a semiconductor stack structure having a first surface including electrical contacts and a second surface attached to a wafer handle;
disposing a first polymer onto the first surface of the semiconductor stack structure to cover the electrical contacts;
removing the wafer handle to expose the second surface of the semiconductor stack structure;
disposing a second polymer onto the second surface of the semiconductor stack structure; and
removing an outer portion of the first polymer to expose the electrical contacts.

23. The method of claim 22 wherein the electrical contacts on the first surface of the semiconductor stack structure are flipchip bumps.

24. The method of claim 22 wherein the semiconductor stack structure has a BOX layer that includes the first surface of the semiconductor stack structure.

25. The method of claim 22 wherein a thermal conductivity of the first polymer and second polymer each range from greater than 2 watts per meter Kelvin (W/mK) to around about 10 W/mK.

26. The method of claim 22 wherein a thermal conductivity of the first polymer and second polymer each range from around about 10 W/mK to around about 50 W/mK.

27. The method of claim 22 wherein a thermal conductivity of the first polymer and the second polymer each range from around about 50 W/mK to around about 6600 W/mK.

28. The method of claim 22 wherein an electrical resistivity of the first polymer and the second polymer each range from around about 10¹² Ohm-cm to around about 10¹⁶ Ohm-cm.

29. The method of claim 22 wherein an electrical resistivity of the first polymer and the second polymer each range from around about 10⁶ Ohm-cm to around about 10¹² Ohm-cm.

30. The method of claim 22 further including depositing a first silicon nitride layer onto the first surface between the first polymer and the semiconductor stack structure, and depositing a second silicon nitride layer onto the second surface between the second polymer and the semiconductor stack structure.

31. The method of claim 30 wherein a thickness of the first silicon nitride layer and a thickness of the second silicon nitride layer each range from greater than 100 Å to around about 5000 Å.

32. The method of claim 22 further including depositing a silicon nitride layer onto the first surface between the first polymer and the semiconductor stack structure.

33. The method of claim 32 wherein a thickness of the silicon nitride layer ranges from greater than 100 Å to around about 5000 Å.

34. The method of claim 22 further including depositing a silicon nitride layer onto the second surface between the second polymer and the semiconductor stack structure.

35. The method of claim 34 wherein a thickness of the silicon nitride layer ranges from greater than 100 Å to around about 5000 Å.
